(19) United States
(12) Patent Application Publication
(10) Pub. No.: US 2004/0115339 A1
(43) Pub. Date: Jun. 17, 2004

(54) Method and apparatus for manufacturing organic EL display and color filter by ink jet method

(76) Inventor: Nobuyuki Ito, Tokyo-to (JP)

Correspondence Address: Richard J. Streit, Ladas & Parry, Suite 1200, 224 South Michigan Avenue, Chicago, IL, 60604, US

(21) Appl. No.: 10/666,674

(22) Filed: Sep. 18, 2003

(30) Foreign Application Priority Data
Sep. 19, 2002 (JP) 2002-273824

(51) Int. Cl. B05D 5/06; H05B 33/00; H05B 33/10

(52) U.S. Cl. 427/66; 427/372.2; 428/690; 428/917; 313/112; 257/88; 257/98; 347/1

(57) ABSTRACT

The object of the present invention is to provide a method and apparatus for manufacturing an EL layer of uniform thickness, causing effective light emission of pixel openings and manufacturing an organic EL display showing sufficient brightness and excellent in practicability, by an ink jet method. Further object is to provide a method and apparatus for manufacturing a color filter excellent in practicability by an ink jet method, in which a dye layer with uniform thickness is formed and optical coloring of uniform tone is conducted at pixel openings.

A method for manufacturing an organic EL display and a color filter by an ink jet method, wherein a device for increasing the temperature of a substrate by heating a stage, and for adjusting a nozzle at cooled temperature are provided to prevent poor ink discharge, and a process of discharging an ink material from a nozzle, subsequently, a process of drying the ink material discharged on a substrate is conducted, while relatively moving the substrate and nozzle. By this manufacturing method, a problem of irregular thickness of an EL layer can be solved.

### BACKGROUND OF THE INVENTION

1. Field of the Invention

The present invention relates to an information display. Particularly, the present invention relates to a method and apparatus for manufacturing an organic electroluminescence (EL) display. Further, the present invention relates to a method and apparatus for manufacturing a color filter.

2. Description of the Related Art

Recently, flat displays are used in many fields and places, and the importance is growing with the progressing of computerization. Nowadays, the typical examples of flat displays are liquid crystal displays (LCD), however, as flat displays based on a different display mode from that of LCD, organic EL, inorganic EL, plasma display panels (PDP), light emitting diode displays (LED), vacuum fluorescent displays (VFD), field emission displays (FED), and the like are being actively developed. These new flat displays are all called a display of self light emitting type, and are significantly different from LCD in the following points and have excellent features not observed in LCD.

LCD is called a light receiving type in which a liquid crystal itself does not emit light and acts as so-called shutter allowing permeation and shutoff of outer light, constituting a display. Therefore, it needs a light source, and in general, a back light is necessary. In contrast, that of light emitting type does not require a separate light source since the apparatus itself emits light. In those of light receiving type such a LCD, a back light is constantly on, irrespective of the form of displaying information, and electric power approximately the same as that under the entire display condition is consumed. In contrast, that of self light emitting type has a theoretical merit that consumption of electric power is smaller as compared with a display of a light receiving type since only portions required to be on depending on display information consume electric power.

Likewise, in LCD, since dark condition is obtained by shading light of a back light source, it is difficult to inhibit light leakage completely, even in small quantity, while in a display of self light emitting type, no light emitting condition is directly dark condition, therefore, theoretical dark condition can be obtained easily, and a display of self light emitting type is overwhelmingly excels also in contrast.

Since LCD utilizes polarization control by double refraction of liquid crystal, there is so-called strong visibility angle dependency, which display condition varies significantly depending on observing direction, while in the case of a display of self light emitting type, this problem scarcely happens.

Further, since LCD utilizes alignment change derived from the dielectric anisotropy of liquid crystal which is an organic elastic substance, the response time against electric signals is theoretically 1 ms or more. In contrast, in the above mentioned technologies being developed, so-called carrier transition such as electron/hole, electron discharge, plasma discharge, and the like are utilized, consequently, the response time is in ns order, and incomparably faster than that of liquid crystal, causing no problem of remaining of animation derived from slowness of the response of LCD.

Among them, study of organic EL is particularly active. Organic EL is also referred to as OEL (Organic EL) or organic light emitting diode (OLED: Organic Light Emitting Diode).

An OEL element and OLED element have a structure in which a layer (EL layer) containing an organic compound is sandwiched in between a pair of electrodes of an anode and a cathode, and a lamination structure of “anode electrode/hole injection layer/light emitting layer/cathode electrode” such as of Tang etc. is the basic structure (see Japanese Patent No. 1526026).

While a lower molecular weight material such as Tangs etc. is used, Nakano et al. use a higher molecular weight material (see Japanese Patent Application Laid-Open (JP-A) No. 3-273087).

Further, improvement in efficiency using a hole injection layer or electron injection layer, or control of light emitting color by doping a fluorescent dye and the like to a light emitting layer, are also conducted.

As the method for manufacturing a display using organic EL, formation of a light emitting layer by discharging a light emitting material using an ink jet discharging apparatus is known (for example, see JP-A No. 11-339957, International Publication No. 00/59267 pamphlet, and JP-A No. 2001-85161).

In the JP-A No. 11-339957, as solution of a light emitting material, a substrate is heat-dried or vacuum-heat-dried after removal of a solvent at room temperature after discharging onto a substrate, however, after a solvent is removed to a certain degree, no effect of flattening of film thickness by forcible drying is obtained.

Furthermore, there are already several trials to forcibly evaporate and dry a solvent, in making a light emitting layer in ink solution condition into a film in an analogous method for manufacturing an organic EL display by an ink jet method, and for example, in the International Publication No. 00/59267 pamphlet, a light emitting material which has been made into ink using a solvent having high boiling point is fed and distributed on a substrate, then, the substrate is heat-treated. This procedure is performed to obtain an effect of drying a substrate by heating, even after formation of a light emitting layer on the entire surface of a substrate by using a solvent of high boiling point to slow the evaporation speed of the solvent and to elongate air drying time. However, removing of a solvent of high boiling point completely cannot avoid a problem that heating treatment at higher temperature is necessary, leading to deterioration of a light emitting material. Though deterioration is not observed in the initial light emitting property, this problem exerts a large influence particularly on shortening of light emitting life. If heating treatment is not conducted at sufficient high temperature, a problem of heat deterioration of a light emitting layer will not occur, however, its leads to significant deterioration of the reliability of a light emitting layer due to the remaining of a solvent in a light emitting layer formed as a film.

In the JP-A NO. 2001-85161, heating treatment is conducted at higher temperature than the softening point of a material of a light emitting layer, to form a light emitting layer, and there is a problem of deterioration of a light emitting material as described above.

The method for manufacturing an organic EL display by an ink jet method will be described. As shown in FIG. 6, an EL material ink in the form of solution is precisely discharged to predetermined openings on a substrate by a finely processed nozzle. In FIG. 6, the surface of the substrate is drawn as flat surface, however, actually as shown in FIG. 9, there are partitions having a height of about 5 μm is formed on a substrate to retain the discharged ink. When the solution is discharged to inside of such fine partitions, formation of so-called meniscus surface condition, by the surface tension of liquid, cannot be avoided. When an EL material ink is dried by evaporation of a solvent under this meniscus surface condition, the meniscus surface condition as ink state is reflected as it is, and the thickness of an EL layer becomes uneven as shown in FIGS. 8 and 9. When electric field is applied to such an EL layer having uneven thickness, electric current concentrates on a smaller thickness portion, and in contrast, electric current does not flow sufficiently to a thick film portion 201, consequently, causing a difference in light emitting brightness.

Actually, when electric field is applied to an EL layer having uneven thickness as shown in FIG. 9, a phenomenon occurs in which only the center portion of pixels having smaller thickness emits light, as shown in the FIG. 11. FIG. 11 shows a pixel opening in the form of rectangle and a pixel opening in the elliptic form. When only the pixel center portion emits light as described above, brightness and efficiency sufficient as a display cannot be attained.

Otherwise, a problem of disconnection of facing electrodes is also important. Usually, since a facing electrode is formed by vapor-depositing a metal thin film, thickness from 100 nm to at most 500 nm is limitation capable of providing stable formation. When thicker than this, a risk of peeling increases due to the tension of a metal itself since it is no longer a thin film. With thickness in this range, when a partition has a height of 5 μm or more, disconnection tends to occur at a corner part of a partition illustrated as 200, as shown in FIG. 9, and a lot of defective pixels occur which electric field is not applied to an EL layer.

By smoothening the form of a partition as shown in FIG. 10, a problem of disconnection can be solved. However, a problem of uneven thickness of an EL layer caused by a meniscus phenomenon is not solved. The problem of uneven thickness due to a meniscus phenomenon occurs not only in an EL light emitting layer but also in other functional layers, for example, a hole injection layer, hole transportation layer, electron injection layer and electron transportation layer when formed from a solution.

On the other hand, regarding also organic EL displays of a mode which uses color filters, or displays using a color filter such as LCD and the like described later, an ink jet method is still attracts attention as a promising method for lowering the manufacturing cost of a color filter and enhancing competitiveness. In manufacturing by an ink jet method, color filters are formed by discharging a dye 400 in the form of solution also through a nozzle, using a black matrix (BM) 401 as a partition as shown in FIG. 16. In comparison with a conventional lithography method, there is a merit of significant improvement in efficiency of utilization of a dye material, however, as shown in FIG. 16, there is a problem that flattening of a dye layer is difficult, same as in the case of an organic EL material described above. In the case of a color filter, tone changes depending on the thickness of a dye layer, therefore, when the film thickness is still uneven as shown in FIG. 16, it will be a color filter having irregularity and useless.

### SUMMARY OF THE INVENTION

The present application has been accomplished in view of the above mentioned point, and the object is to provide a method and apparatus in which an uniform thickness EL layer is formed, a pixel opening emits light effectively, and an organic EL display having sufficient brightness and excellent in practice is manufactured by an ink jet method. The further object thereof is to provide a method and apparatus for manufacturing a color filter excellent in practice, by an ink jet method, in which an uniform thickness dye layer is formed and optical colorization of uniform color tone is conducted at a pixel opening.

The present invention is a method for manufacturing an organic EL display by an ink jet method in which an organic EL material in the form of solution is discharge-placed on a previously heated substrate, and immediately after, a drying by heating process is forcibly conducted. Further, the present invention is a method for manufacturing an organic EL display in which an organic EL material is placed on the substrate and dried by heating continuously by relatively moving a nozzle for discharging an organic EL material and a substrate. By this manufacturing method, the above mentioned problem of uneven thickness of an EL layer can be solved.

By using the present invention, when an organic EL display and a color filter are manufactured by an ink jet method, flattening of an organic EL layer and a color filter coloring layer is easily attained, and an organic EL display and a color filter having high material utilizing efficiency and excellent in uniformity property can be provided.

### BRIEF DESCRIPTION OF THE DRAWINGS

FIG. 1 is a sectional constitutional view of a method and apparatus for manufacturing a display according to a first example of the present invention.

FIG. 2 is a front view of a method and apparatus for manufacturing a display according to a first example of the present invention.

FIG. 3 is one example of a nozzle cooling temperature adjusting mechanism according to an example of the present invention.

FIG. 4 is a sectional view of a method and apparatus for manufacturing a display according to a second example of the present invention.

FIG. 5 is a front view of a method and apparatus for manufacturing a display according to a second example of the present invention.

FIG. 6 is a constitutional view showing a method for forming an organic EL display by an ink jet method.

FIG. 7 is a process view showing a process of flattening an organic EL display by an ink jet method.

FIG. 8 is a view showing the condition of an organic EL layer by an ink jet method when flattening is not performed.

FIG. 9 is a section constitutional view of a display manufactured by conventional manufacturing methods.

FIG. 10 is a section constitutional view of another conventional display manufactured and improved by conventional manufacturing methods.

FIG. 11 is a view showing the displaying condition of a display manufactured by conventional manufacturing methods.

FIG. 12 is a section constitutional view of an organic EL element.

FIG. 13 is another section constitutional view of an organic EL element.

FIG. 14 is a circuit diagram showing the constitution of a pixel of an active driving organic EL display.

FIG. 15 is a constitutional view showing the constitution of a matrix pixel of an active driving organic EL display.

FIG. 16 is a sectional view of a color filter manufactured by a conventional ink jet method.

FIG. 17 is an example of an electronic device equipped with a display of the present invention.

### DESCRIPTION OF THE PREFERRED EMBODIMENTS

Embodiments of the present invention will be illustrated in detail referring to drawings.

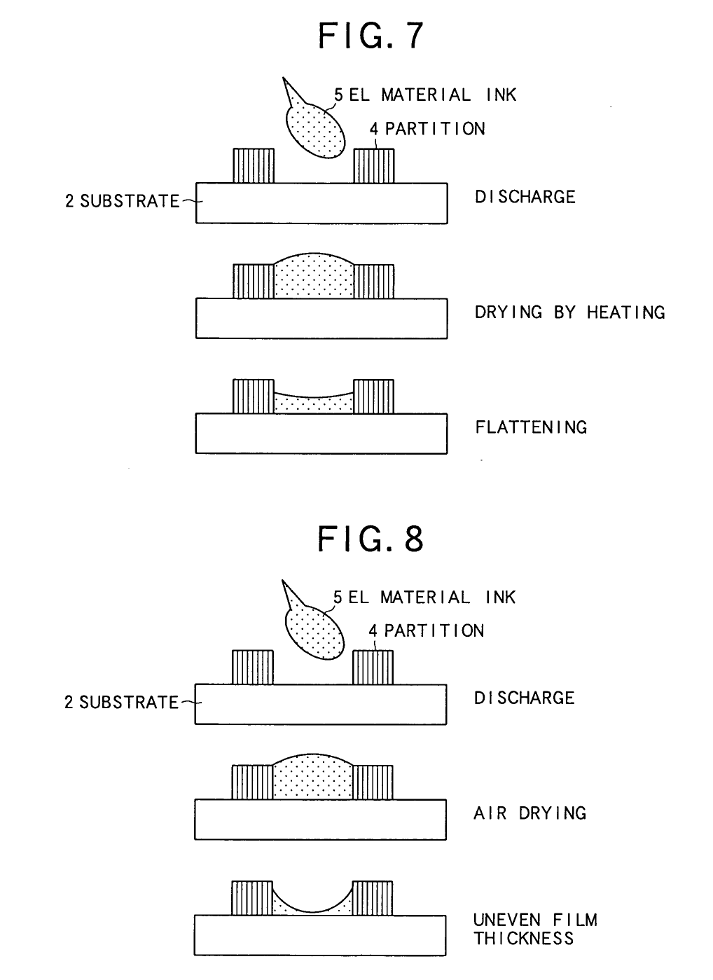

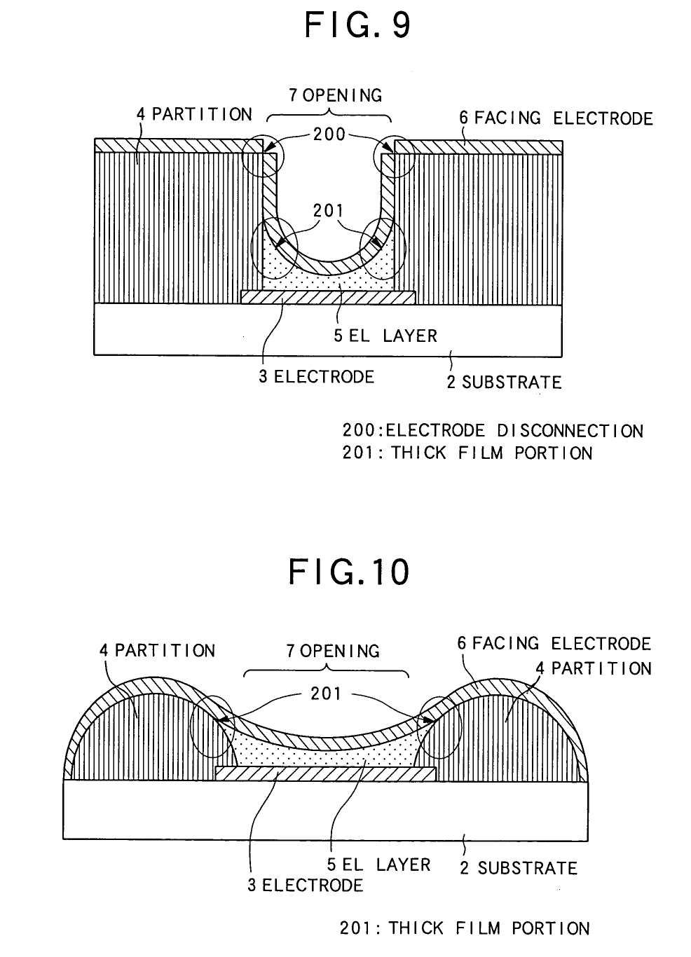

First, the effect of the present invention will be described referring to FIGS. 7 and 8. FIG. 8 is a view showing a film formation process of an organic EL material by a conventional ink jet method and the condition of the formed organic EL layer. An organic EL material in the form of ink discharged by an ink jet method into a space, formed by partitions on a substrate, is formed into a convex shape to the substrate surface due to the surface tension in the same manner as usual liquid when reaches to a substrate. If the above mentioned is air-dried as it is, a solvent is gradually evaporated to cause so-called meniscus shape, giving uneven layer thickness. Particularly, in the case of a pixel of a display, the diameter of an opening is usually is very small as about 10 μm in terms of circle, and in order to fit into this size, a liquid drop is also vary small.

Thus, under small size liquid drop condition, the surface area is by far larger as compared with the volume of an ink, therefore, drying by evaporation from the surface is dominant as compared with evaporation from inside of a liquid drop of a solvent, and a change in the form of the film upper surface (here, lowering of liquid surface) occurs. In addition, because of the surface tension of a partition, a meniscus shape is formed and the film thickness becomes uneven.

FIG. 7 is a view showing the case of forcible drying by heating immediately after the discharge of an ink, and the inventors have found that when such forcible drying is conducted, the meniscus shape of the film surface is lightened and the film thickness becomes even. In view of the above mentioned solvent drying condition, it is believed that by conducting forcible heating, the liquid drop is heated entirely, and a solvent in the liquid drop is forcibly evaporated, leading to a difficulty in generation of a change in the form of the film upper surface.

Further, an effect of flattening of film shape by such forcible drying is required to be performed as soon as possible after the discharge, and it is effective to drying by heating immediately after discharge, at most within 60 seconds. Once uneven film thickness is formed by air drying, film shape does not change even by forcible drying.

As the manufacturing apparatus for realizing the above mentioned manufacturing method precisely on a substrate having a plurality of fine pixel openings, an apparatus for manufacturing an organic EL display comprising: a mechanism of heating a substrate by previously raising the temperature of a stage supporting the substrate; a mechanism of discharging an organic EL material from a nozzle and place the material on predetermined position of the substrate; a mechanism of drying the organic EL material by heating immediately after discharging, is manufactured. Further, an apparatus for manufacturing an organic EL display in which drying by heating and placing on a substrate of an organic EL material are continuously conducted by relatively moving a nozzle for discharging an organic EL material and a substrate. Additionally, to eliminate the temperature rise of a nozzle for discharging an organic EL material by radiation heat from stage heating, a nozzle cooling temperature adjusting mechanism was provided to prevent this.

The present invention will be illustrated more in detail with explanation of these manufacturing apparatuses.

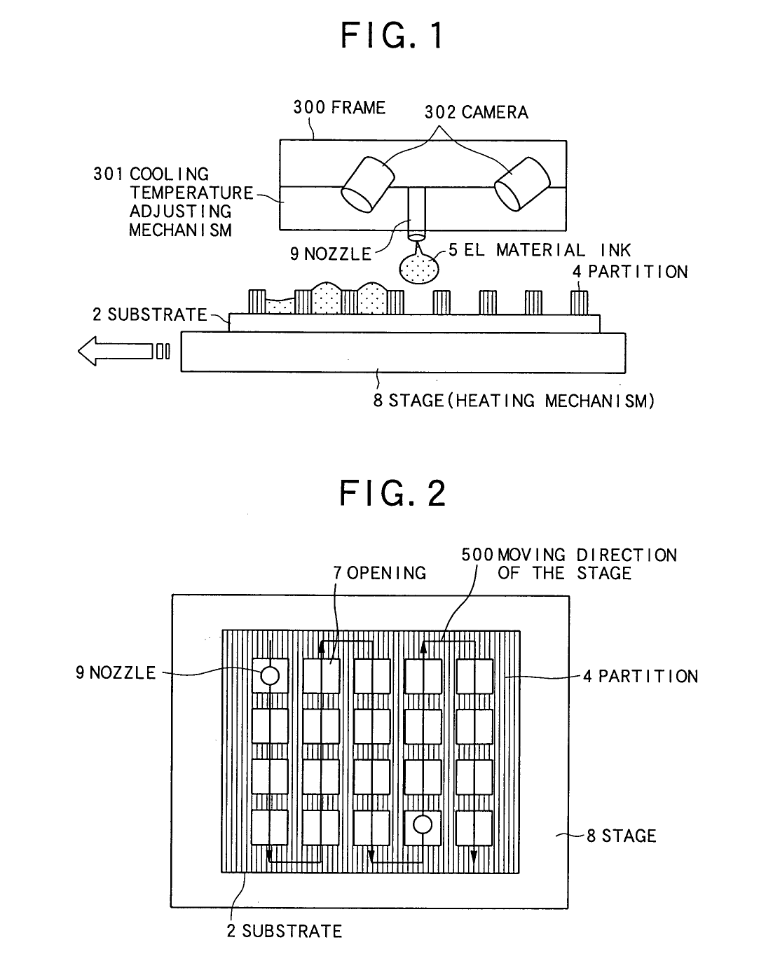

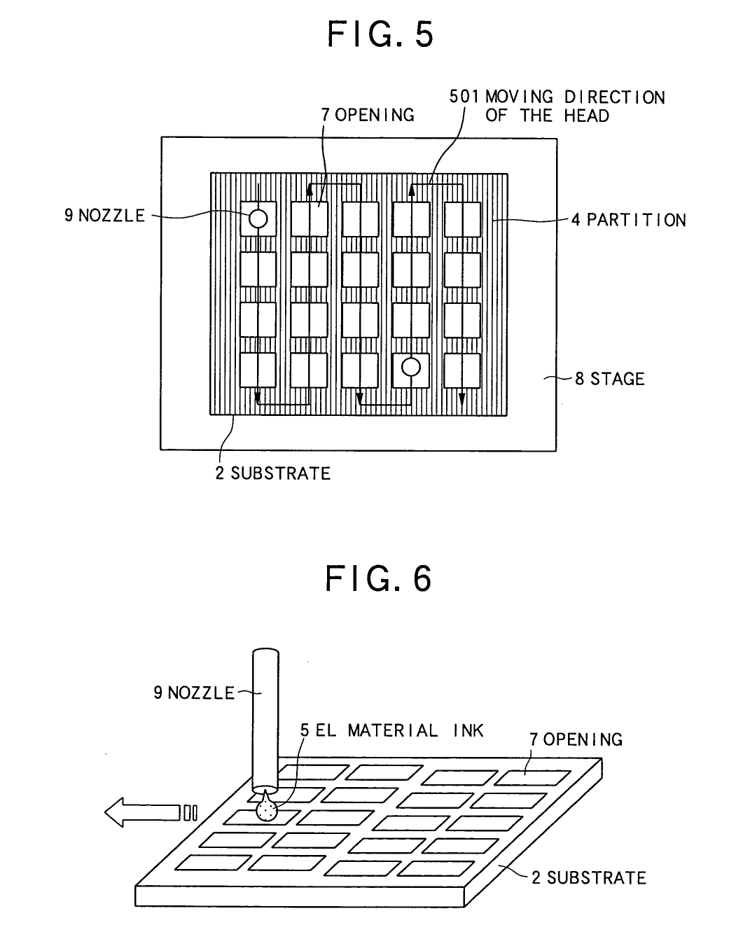

The manufacturing apparatus of precisely realizing the method for manufacturing an organic EL display of the present invention, on a substrate having a plurality of fine pixel openings, has a basic structure shown in FIG. 1. The manufacturing apparatus of the present invention comprises a head portion having a nozzle 9 for ink discharging, a stage 8 supporting the substrate having a partition 4 as described above in the explanation of an ink jet method, and a device for moving them. The stage has a device of heating a substrate, and the head portion comprises a nozzle and a temperature adjusting mechanism 301 which cools the nozzle to prevent the increase of the temperature, installed and integrated on a frame 300. Also a camera 302 is provided for observing the discharging condition and drying condition of an EL material ink 5. When the temperature of a substrate is increased by previously heating the stage, an organic EL layer having uniform film thickness and having remarkably improved flatness as compared with conventional layers can be formed by sufficient forcible drying by heating in a short time until air drying, after ink discharge. In FIGS. 1 and 2, by discharging and drying by heating one after another to a lot of pixels while moving a stage toward the direction shown by an arrow, manufacturing with good precision and with high through put is possible even in the case of a large size substrate and a lot of pixels of high precision. A nozzle may be moved as shown in FIGS. 4 and 5, and of course, both of the head and the stage may be moved.

Increase of the temperature of a substrate by heating a stage is the simplest method for forcible drying by heating, however, an influence on a nozzle cannot be ignored. When a stage is heated previously to constant temperature, a nozzle is also heated by its radiation heat and a solvent is evaporated, by this, the concentration of an ink changes and conditions for discharge of an ink vary remarkably, and additionally, a nozzle is clogged, to cause poor discharging. Usually, to control the discharging, splashing direction, reaching position and the like of an ink precisely by an ink jet method, it is generally necessary that the distance between a nozzle and object is 1 mm or less, for example, several 100 μm, namely, the nozzle and object are placed in close proximity, and by merely heating a stage, a nozzle is also heated and generation of poor discharge cannot be avoided.

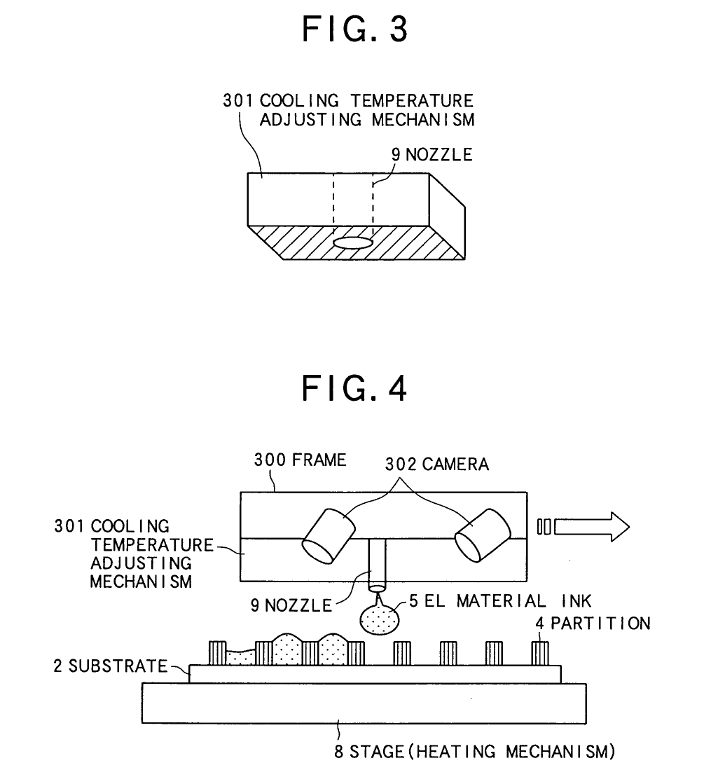

In the present invention, a mechanism of adjusting temperature which cools a nozzle is provided together with a stage heating mechanism so that the temperature of a nozzle does not increase. As this temperature adjusting mechanism, for example, a chiller, a Peltier element, or a combination thereof, in which cooling water, cooling oil, or gas of low temperature such as liquid nitrogen and the like is circulated in a groove provided in a block surrounding a nozzle as shown in FIG. 3 can be used, however, other methods can also be used as long as it is a mechanism capable of adjusting temperature by cooling.

Though one nozzle is drawn in FIGS. 1, 2, 4 and 5, it is not practical to effect discharge treatment on all pixels by using one nozzle from the standpoints of treatment speed and manufacturing time. Actually, it is desirable to effect discharge treatment simultaneously on a plurality of columns of pixels using a plurality of nozzles.

Naturally, when not only an organic EL light emitting layer but also other functional layers, for example, a hole injection layer, hole transportation layer, electron injection layer and electron transportation layer are made into a solution, the same effect can be obtained.

In this specification, a pixel electrode and facing electrode correspond to either an anode or cathode, to constitute a pair of electrodes. All layers provided in between them are generically called an EL layer, and the above mentioned hole injection layer, hole transportation layer, light emitting layer, electron injection layer and electron transportation layer are included in this.

FIG. 12 shows the sectional structure of an organic EL element.

Organic EL emits light when electric field is applied between electrodes and electric current is passed through an EL layer. Conventionally, only fluorescent emission due to returning from singlet excited state to ground state is used, however, as results of recent studies, phosphorescence emission due to returning from triplet excited state to ground state can be utilized effectively, to improve efficiency.

Usually, a translucent electrode 3 is formed on a translucent substrate 2 such as a glass substrate and plastic substrate, then, an EL layer 5 and a facing electrode 6 are formed in this order. In general, an anode is constituted of a translucent electrode such as ITO and the like, and a cathode is a non-translucent electrode constituted of a metal, in many cases.

Though not shown in FIG. 12, since an organic EL element shows remarkable deterioration in properties by moisture and oxygen, reliability thereof is insured, in general, by filling an inert gas so that an element does not contact with moisture and oxygen, then, using another substrate, or conducting so-called sealing by vapor deposition of a thin film.

When an organic EL element is used as a display, the mode can be roughly classified into a passive matrix mode and active matrix mode depending on the electrode constitution and driving method, as for LCD. In the passive matrix mode, a pair of electrodes are constituted of a horizontal electrode and vertical electrode mutually crossing while sandwiching an EL layer, and its structure is simple, however, for displaying an image, moment brightness has to be enhanced by the multiple of the number of scanning lines by time sharing scanning, and in usual VGA or more displays, moment brightness of organic EL of over 10000 cd/m² is necessary, causing a lot of practical problems as a display. In the active matrix mode, a pixel electrode is formed on a substrate on which TFT or the like has been formed, and an EL layer and facing electrode are formed, namely, its structure is complicated as compared with the passive matrix method, however, it is advantageous as an organic EL display in many points such as light emitting brightness, consumption power and crosstalk.

Further, a display of active matrix mode, using a polycrystalline silicon (polysilicon) film and a continuous grain boundary silicone (CG silicon) film, manifests higher electric charge mobility than an amorphous silicon film, therefore, it can treat TFT with large electric current and is suitable for driving of organic EL which is a current driven element. Since polysilicon TFT and CG silicon TFT can move at high speed, various control circuits, conventionally treated by exterior IC, are formed on the same substrate as for a display pixel, and there are a lot of merits such as reduction of the size of a display, lowering the cost, multi-function and the like.

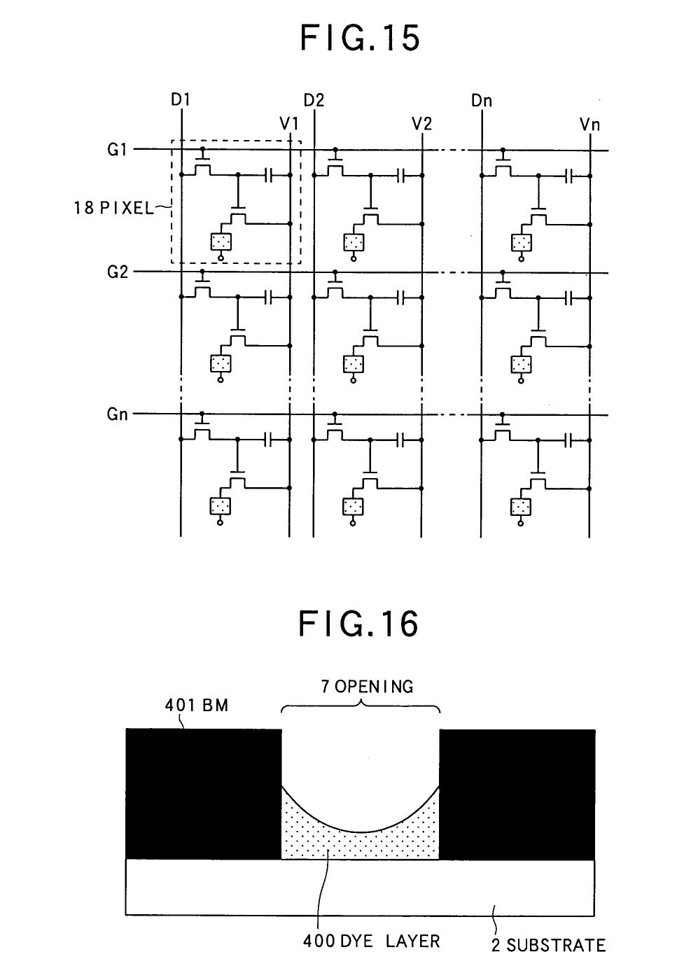

FIG. 14 shows a typical pixel circuit constitution of an active matrix organic EL display. In addition to bus lines such as a scanning line G 11, data signal line D 12 and power supply line V 13, the apparatus comprises switching TFT 14, gate retention capacity 15, driving TFT 16 and EL element 17. When a gate of switching TFT, selected by the scanning line G, is opened and signal voltage corresponding to emission strength is applied from the date signal line D to a TFT source, a gate of driving TFT is opened in analogue-wise responding to magnitude of signal voltage, and this condition is retained in gate retention capacity. When voltage is applied from the power supply line V to a source of driving TFT, electric current corresponding to the degree of opening of a gate flows into an EL element, to cause light emission in gradation depending on the magnitude of signal voltage. FIG. 15 shows the structure of an actual display in which pixels 18 are placed in the form of matrix.

The circuit constitution and driving method of an organic EL display include, as other examples, a method in which the number of TFT is further increased, “Pixel-Driving Methods for Large-Sized Poly-Si AM-OLED Displays” Asia Display/IDW'01 P. 1395-1398 by Yumoto et al., and digital gradation driving methods such as time sharing gradation by Mizukami et al. “6-bit Digital VGA OLED” SID'00 P. 912-915, area division gradation by Miyashita et al. “Full Color Displays Fabricated by Ink-Jet Printing” Asia Display/IDW'01 P. 1399-1402 and the like, any of these technologies may be used.

Even under passive matrix mode, a simple display having a small number of scanning lines can realize a practical apparatus utilizing the simplicity of the structure. Further, development of a phosphorescent emitting material is being progressed in addition to conventional fluorescent emitting materials, and emitting efficiency is improved significantly. By utilizing these light emitting materials having high light emitting efficiency, there is a possibility of solving the conventional problem in the passive matrix mode.

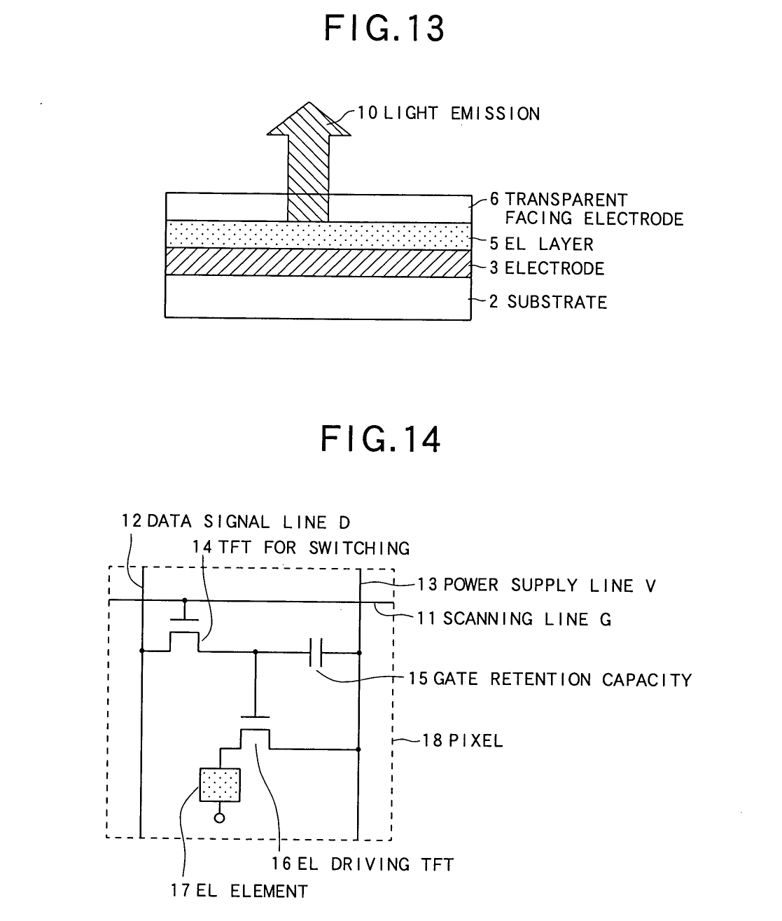

Also a top emission structure, in which light emission 10 is taken out toward the opposite direction against a substrate as shown in FIG. 13, is under investigation. In contrast to the top emission structure, a structure shown in FIG. 12 is called a bottom emission structure in some cases. In the top emission structure, particularly in a display of active matrix mode, the light emitting area rate is not limited by circuit constitutions such as TFT and bus lines, so that higher multi-functional and complicated circuits can be formed, therefore, being developed as a promising technology.

In the present invention, any of the above mentioned technologies may be used in organic EL.

The method of attaining colorization includes a CF mode in which a white light emitting layer and color filters (CF) of three colors R, G and B are combined, and a CCM (Color Changing Medium) mode in which a blue light emitting layer and an R and G fluorescent converting dye filter are combined, in addition to the most basic three color juxtaposition mode in which organic EL materials of the three colors R, G and B are precisely placed per each pixel of a display.

When colorization modes are compared, in the CF method, a white light emitting material is necessary, and an apparent white organic EL material for illumination use is realized. However, a real white organic EL material having spectra of three colors R, G and B is not realized yet, and there is a shortcoming that the utilizing efficiency of light emission will become one-third, due to the use of color filters.

In the CCM mode, only a blue emitting material is used, therefore, its light emitting efficiency and R-G converting efficiency of a CCM filter are important, however, sufficient efficiency cannot be obtained easily, namely, the CCM mode is not practical yet. The CF mode is insufficient in the point of color reproducing, in the same way that LCD of the CD mode has drawbacks in reproducing of TV images. The CCM mode is also one kind of filter mode, and is common in the above respect, and the three color juxtaposition mode is excellent in color reproducing in that composition of each color light emitting material is slightly adjusted. Since the CF mode and CCM mode have shortcomings such as increase in the thickness of an element due to use of filters, increase in the number of parts, and the like, thus the juxtaposition mode is favorable overall.

As the mode of forming three color juxtaposition fine pixels, a mask vacuum vapor deposition method is used in the case of a low molecular weight material, and in the case of a high molecular weigh material, it is made into a solution and an ink jet method, printing method, transfer method and the like are used. Recently, a low molecular weight material which can be coated is also being developed.

In the case of a three color juxtaposition color display, the mask vacuum vapor deposition method of a low molecular weight material has a problem that it is difficult to respond to a large scale display and produce a large number of displays using a large size substrate, due to restriction of a vacuum apparatus and a vapor deposition mask. This means that there is no problem in manufacturing of trial manufacturing level in the development, however, requests of the market cannot be responded in terms of tact and cost in the full manufacturing stage. On the other hand, high molecular weight materials and low molecular weight materials which can be coated can be formed into a film by wet processes such as a ink jet method, printing method, casting method, alternate adsorption method, spin coating method, dip method and the like, therefore, the above mentioned problems for responding to a large scale substrate are scarce, and particularly in the case of an ink jet method, manufacturing of a highly precise display is also possible, therefore, this method can be the most promising method in the future.

In the mask vacuum vapor deposition method, when a light emitting material is selectively placed on a pixel portion, most of the material adheres to a mask, leading to remarkable decrease in material utilizing efficiency.

In contrast, the ink jet method is a method of the highest material utilizing efficiency since a light emitting material can be selectively placed only on necessary pixel portions.

The manufacturing method and manufacturing apparatus of realizing uniform thickness formation of a light emitting layer of an organic EL display by an ink jet method have been described above, and these descriptions are applied also to the method and apparatus for manufacturing a color filter by an ink jet method except that an organic EL material is changed to a dye material.

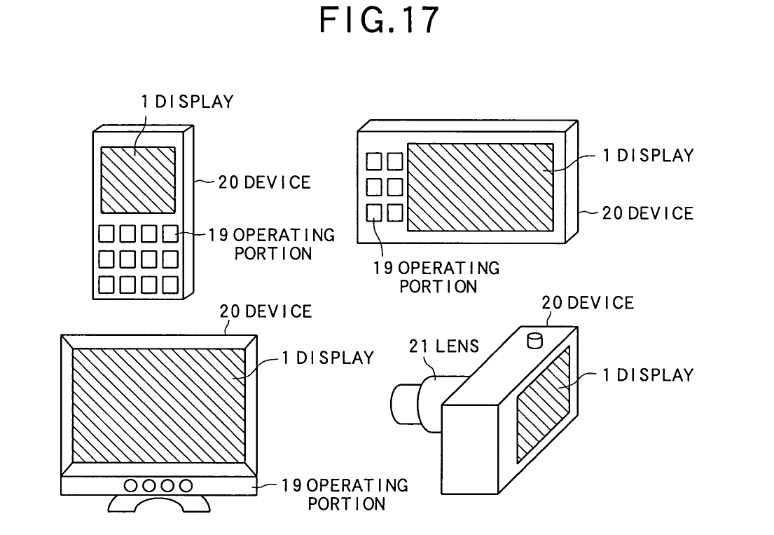

As the organic EL display, organic EL display manufactured by using a color filter and device 20 as shown in FIG. 17 carrying LCD as a display 1, provided by using the present invention, a portable telephone provided with an operating portion 19 and a terminal of PDA (Personal Digital Assistant) type, PC (Personal Computer), TV receiver set, video camera, digital camera, and the like can be listed.

### EXAMPLES

The present application has been illustrated above, and the present application will be illustrated further in detail based on examples.

The present application is not limited to them.

### Example 1

The following solution was prepared as an example of the present invention.

(Preparation of organic EL layer forming coating solution)

| | | |
|---|---|---|
| Polyvinylcarbazole | 70 | parts by weight |
| Oxadiazole compound | 30 | parts by weight |
| Coumarin 6 (* fluorescent dye) | 1 | part by weight |

These were dissolved in a proportion of 0.5wt% in tetralin (solvent), to produce an organic EL material ink for ink jet.

Ink Jet Apparatus

An ink jet apparatus shown in FIGS. 1 and 2 was fabricated. On a stage, a temperature adjusting mechanism composed of a built-in heater and a temperature sensor was provided, and also on the side of a nozzle, a temperature adjusting mechanism utilizing a Peltier element was provided. For fixing a substrate, a vacuum adsorption mechanism was provided on a stage. For observing the condition of ink discharging and drying by heating, a CCD camera was provided. A head portion provided with a nozzle and heater is fixed, and mechanisms for X (longitudinal), Y (lateral), Z (up and down) and θ (rotation) and motors were provided so that a stage fixing a substrate can move in any directions. Alignment ability was provided for conducting precise aligning with a nozzle, utilizing an alignment mark on a substrate. The distance between a nozzle and substrate, the volume of one drop of an ink discharged from a nozzle, the number of discharging drops per unit time, the stage moving speed, the discharging schedule of an ink from a nozzle, the heater temperature and the nozzle temperature were set to be variable as the parameter.

Manufacturing of Substrate

Using a polysilicon film, an active matrix substrate for organic EL having a pixel circuit constitution shown in FIG. 14 was manufactured on a glass substrate. On a substrate of 17 inch diagonal (size: 300 mm×370 mm), pixels of XGA (768×1024) standard were designed. A substrate on which electrodes and partitions are formed as shown in the sectional form in FIG. 10 was prepared. Partitions are placed so as to cover the electrode ends so that the partitions act also as electrode insulating layer. As the electrode, a transparent electrode such as ITO, NESA film, IZO and the like was formed into a film, and patterned by etching. As the partition, a photosensitive resist OFPR-800 (viscosity: 500 cp) manufactured by Tokyo Ohka Kogyo Co., Ltd. was spin coated at 1200 rpm and prebaked at 110° C., then, exposed by using a photomask, developed, and postbaked at 240° C. The partition was formed to have a height (film thickness) of 6 μm under the above mentioned conditions. The shape of thus formed partition can be confirmed easily by using a scanning type electron microscope (SEM) and the like. It was confirmed that the partition has a convex curved sectional shape to the substrate surface, and the sectional shape is a part of arc. A transparent electrode is used in an element structure of bottom emission, and a transparent substrate is used. It is also possible that a metal is used as an electrode to give a top emission element structure.

Manufacturing of Organic EL Display

After cleaning of a substrate, PEDOT/PSS (polythiophene: Bayer CH8000) with hole injecting property was coated by a thickness of 80 nm by spin coating, and baked at 160° C. to form a so-called buffer layer.

Using the above mentioned ink jet apparatus, the above mentioned organic EL material inks of R, G and B were continuously discharged to pixel openings on PEDOT and dried by heating, to form three color juxtaposition organic EL light emitting layers. To make the flattened film thickness after drying to be 100 nm, the parameter of the ink jet apparatus was adjusted, and the temperature of drying by heating was 100° C. By setting the nozzle temperature at from 25° C. to 30° C., poor ink discharge could be prevented.

Subsequently, a MgAg alloy (Mg:Ag=10:1) was vapor-deposited to give a thickness of 150 nm, and on this, Ag was vapor-deposited to form a protective layer having a thickness of 200 nm, to obtain a cathode. When an active matrix display is manufactured by using a TFT substrate as in this case, a cathode is formed on the entire surface, and in the case of manufacturing of passive matrix display, a cathode is formed in the form of stripe so as to cross an electrode pattern on a substrate.

Finally, the above was sealed by a separately prepared glass plate and a UV curing sealing material, to complete an organic LE display.

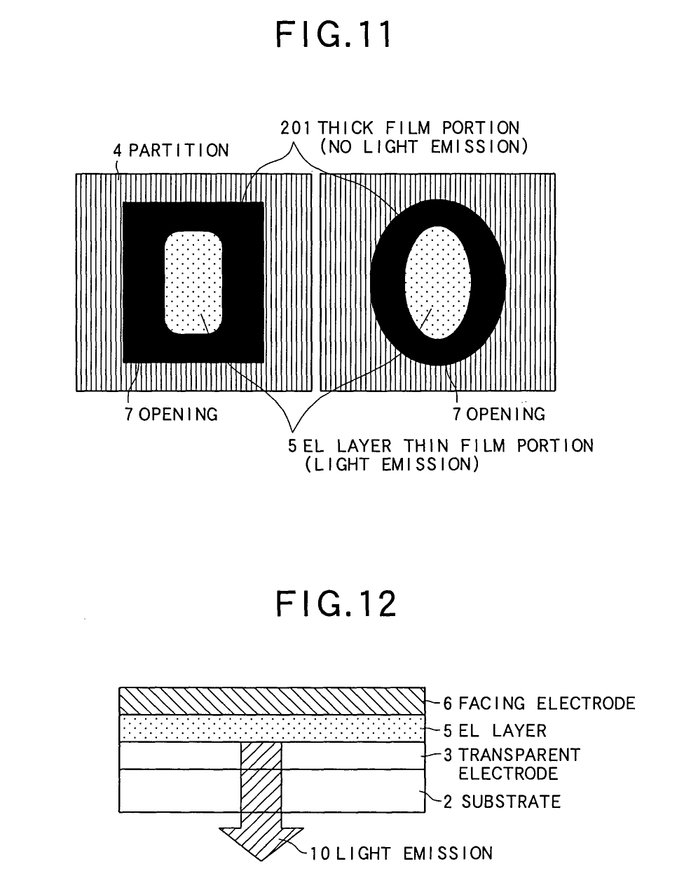

When a control circuit was connected to thus manufactured organic EL display and image signals were applied to drive the apparatus, poor emission derived from uneven thickness of an EL layer as shown in FIG. 11 did not occur, and uniform and bright color image display could be conducted on the entire surface.

### Comparative Example 1

As a comparative example, the same procedure as in Example 1 was conducted except the stage heating was turned off, to manufacture an organic EL display. When a control circuit was connected to this organic EL display and image signals were applied to drive the apparatus, poor light emitting images derived from uneven thickness of an EL layer as shown in FIG. 11 occurred in a large number, and uniform image display could not be conducted. Further, brightness under the same applied voltage decreased significantly, and its efficiency also lowered significantly.

### Comparative Example 2

As a comparative example, the same procedure as in Example 1 was conducted except the nozzle temperature adjustment was not effected, to manufacture an organic EL display, however, poor ink discharge occurred in a large number, and an organic EL display could not manufactured.

### Example 2

The same procedure as in Example 1 was conducted except, as shown in FIGS. 4 and 5, a stage was fixed, and mechanisms for X (longitudinal), Y (lateral), Z (up and down) and θ (rotation) and motors were provided so that a head portion could move in any directions, and an organic EL display capable of conducting uniform and bright color image display on the entire surface as in Example 1 could be manufactured.

### Example 3

The same procedure as in Examples 1 and 2 was conducted except that also a buffer layer PEDOT/PSS formed selectively on pixel openings by an ink jet method while forcibly drying by heating.

In the case of spin coating film formation in Examples 1 and 2, slight irregularity was observed after spin coating due to the influence of a partition surrounding the pixel, however, by forming by an ink jet method, film formation irregularity of PEDOT could be solved. By merely forming by an inkjet method, a problem of irregular thickness in pixels of PEDOT should newly occurs, however, by the effect of drying by heating as in Examples 1 and 2, uniformity in the substrate surface could be improved while maintaining the same display ability and efficiency as in the case of spin coat.

### Example 4

A color filter was manufactured by an ink jet method in the same manner as in Examples 1 and 2 except the organic EL material was changed to a pigment dye. Conventionally, a color filter manufactured by an ink jet method had a problem of irregular tone in pixels derived from irregular thickness of a dye layer as in FIG. 16, however, in this example, an excellent color filter could be manufactured without generating irregular tone.

Examples of the present invention have been described in the above, however, the present invention is not limited to the above.

What is claimed is:

1. A method for manufacturing an organic EL display by an ink jet method, wherein an uniform organic EL layer is formed by a process of discharge-placing, on a heated substrate, at least an organic EL material in the form of solution, and a process of drying the organic EL material in the form of ink, placed on the substrate, by heating.

2. The method for manufacturing an organic EL display according to claim 1, wherein the organic EL material is discharged, on a heated substrate, while controlling to a constant temperature by cooling.

3. The method for manufacturing an organic EL display according to claim 1, wherein the organic EL material is uniformly formed at a plurality of pixel openings placed in the form of two-dimensional matrix on a substrate, while relatively moving the nozzle and the substrate.

4. An apparatus for manufacturing an organic EL display, comprising: a heating temperature controlling mechanism on a stage supporting a substrate; a nozzle cooling temperature controlling mechanism; mechanism of discharge-placing, on a heated substrate, at least an organic EL material in the form of solution which is kept under constant temperature condition; and a mechanism of drying the organic EL material in the form of ink, placed on the substrate, by heating.

5. The apparatus for manufacturing an organic EL display according to claim 4, wherein the nozzle cooling temperature controlling mechanism is a chiller, a Peltier element, or a combination thereof.

6. A method for manufacturing a color filter by an ink jet method, wherein a uniform coloring layer is formed by a process of discharge-placing, on a heated substrate, a dye material in the form of solution, and a process of drying the dye material in the form of ink, placed on the substrate, by heating.

7. The method for manufacturing a color filter according to claim 6, wherein the dye material is discharged, on a heated substrate, while controlling to a constant temperature by cooling.

8. The method for manufacturing a color filter according to claim 6, wherein the dye material is uniformly formed at a plurality of pixel openings placed in the form of two-dimensional matrix on a substrate, while relatively moving the nozzle and the substrate.

9. An apparatus for manufacturing a color filter comprising: a heating temperature controlling mechanism on a stage supporting a substrate; a nozzle cooling temperature controlling mechanism; mechanism of discharge-placing, on a heated substrate, at least a dye material in the form of solution which is kept under constant temperature condition; and a mechanism of drying the dye material in the form of ink, placed on the substrate, by heating.

10. The apparatus for manufacturing a color filter according to claim 9, wherein the nozzle cooling temperature controlling mechanism is a chiller, Peltier element, or a combination thereof, surrounding the nozzle.

11. An electronic device using an organic EL display, as a display, manufactured by the manufacturing method according to claim 1.

12. An electronic device using an organic EL display, as a display, manufactured by the manufacturing apparatus according to claim 4.

13. An electronic device using an organic EL display or liquid crystal display, as a display, using a color filter manufactured by the manufacturing method according to claim 6.

14. An electronic device using an organic EL display or liquid crystal display, as a display, using a color filter manufactured by the manufacturing apparatus according to claim 9.
